(19) United States
(12) Patent Application Publication
(10) Pub. No.: US 2025/0023442 A1
(43) Pub. Date: Jan. 16, 2025

(54) CURRENT DETECTION CIRCUIT, SWITCHING POWER SUPPLY CONTROLLER, LIGHT EMITTING ELEMENT DRIVER, AND MOTOR DRIVER

(71) Applicant: ROHM CO., LTD., Kyoto (JP)

(72) Inventor: Hironori SUMITOMO, Kyoto (JP)

(21) Appl. No.: 18/764,787

(22) Filed: Jul. 5, 2024

(30) Foreign Application Priority Data
Jul. 10, 2023 (JP) 2023-112845

(51) Int. Cl. H02M 1/00; H02M 1/32; H02P 21/22; H02P 27/06

(52) U.S. Cl. CPC H02M 1/0009; H02M 1/32; H02P 21/22; H02P 27/06

(57) ABSTRACT

A current detection circuit includes: a first comparator configured to compare a sense voltage, which corresponds to a current flowing through a switching element when the switching element is turned on, and a threshold voltage; and a determiner configured to determine, based on an output of the first comparator, whether or not a timing at which a magnitude relationship between the sense voltage and the threshold voltage is reversed after the switching element is turned on is before a predetermined time elapses after the switching element is turned on.

### CROSS-REFERENCE TO RELATED APPLICATION

This application is based upon and claims the benefit of priority from Japanese Patent Application No. 2023-112845, filed on Jul. 10, 2023, the entire contents of which are incorporated herein by reference.

### TECHNICAL FIELD

The present disclosure relates to a current detection circuit, a switching power supply controller, a light emitting element driver, and a motor driver.

### BACKGROUND

In the related art, as a technique for detecting an output current of a switching power supply device, there is a current detection method that uses a potential difference between both ends of a sense resistor provided at a stage subsequent to a capacitor that smoothes an output voltage of the switching power supply device.

### BRIEF DESCRIPTION OF DRAWINGS

The accompanying drawings, which are incorporated in and constitute a part of the specification, illustrate embodiments of the present disclosure.

FIG. 1 is a diagram showing a configuration of a switching power supply device according to an embodiment of the present disclosure.

FIG. 2 is a diagram showing an example of an operation of a current detection circuit.

FIG. 3 is a diagram showing an example of an operation of a current detection circuit.

FIG. 4 is a diagram showing an example of an operation of a current detection circuit.

FIG. 5 is a diagram showing an example of an operation of a current detection circuit.

FIG. 6 is a diagram showing a configuration of a switching power supply device according to a modification.

FIG. 7 is a diagram showing a schematic configuration example of a light emitting device.

FIG. 8 is a diagram showing a schematic configuration example of a motor device.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In the present disclosure, a metal oxide semiconductor (MOS) field effect transistor refers to a field effect transistor having a gate structure including at least three layers selected from the group of a “layer made of a conductor or a semiconductor such as polysilicon with a low resistance value,” an “insulating layer,” and a “P-type, N-type, or intrinsic semiconductor layer.” That is, a gate structure of the MOS field effect transistor is not limited to a three-layer structure of metal, oxide, and semiconductor.

In the present disclosure, a constant current means a current that is constant in an ideal state, and is actually a current that may vary slightly due to a temperature change, etc.

### <Switching Power Supply Device>

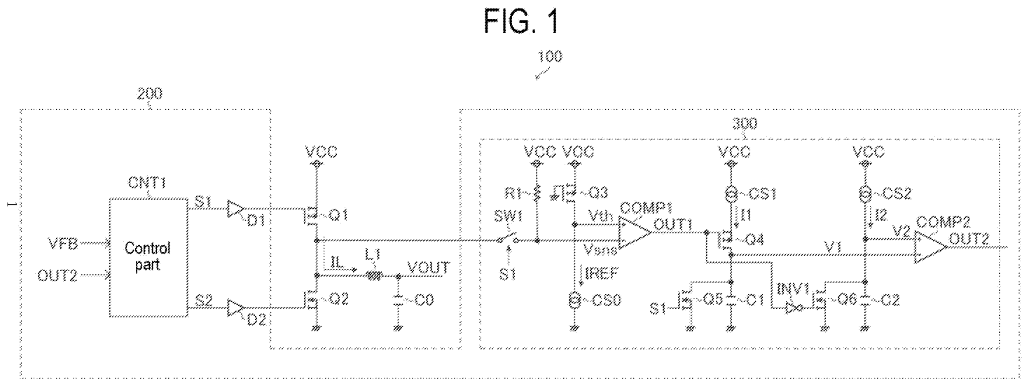

FIG. 1 is a diagram showing a configuration of a switching power supply device according to an embodiment of the present disclosure. The switching power supply device 100 includes a switching power supply controller 200 which is a semiconductor integrated circuit device, a P-channel type MOS field effect transistor Q1 and an N-channel type MOS field effect transistor Q2 which are switching elements, an inductor L1, and an output capacitor C0. In the present embodiment, the switching elements are externally connected to the switching power supply controller 200, but may be built into the switching power supply controller 200. Further, in the present embodiment, the switching elements are MOS field effect transistors, but may be elements other than a MOS field effect transistor.

The P-channel type MOS field effect transistor Q1 and the N-channel type MOS field effect transistor Q2 are connected in series. The P-channel type MOS field effect transistor Q1 is a high-side switch provided on the higher potential side than the N-channel type MOS field effect transistor Q2. The N-channel type MOS field effect transistor Q2 is a low-side switch provided on the lower potential side than the P-channel type MOS field effect transistor Q1.

A power supply voltage VCC is applied to a source of the P-channel type MOS field effect transistor Q1. A source of the N-channel type MOS field effect transistor Q2 is connected to a ground potential. By switching between the P-channel type MOS field effect transistor Q1 and the N-channel type MOS field effect transistor Q2, a pulse-shaped switch voltage is generated at a connection node between the P-channel type MOS field effect transistor Q1 and the N-channel type MOS field effect transistor Q2.

The inductor L1 and the output capacitor C0 smooth the switch voltage generated at the connection node between the P-channel type MOS field effect transistor Q1 and the N-channel type MOS field effect transistor Q2 to generate an output voltage VOUT.

The switching power supply controller 200 includes a control part CNT1, drivers D1 and D2, and a current detection circuit 300.

The control part CNT1 outputs control signals S1 and S2 based on a feedback voltage VFB. The feedback voltage VFB is a voltage based on the output voltage VOUT. The feedback voltage VFB may be the output voltage VOUT itself or may be a divided voltage of the output voltage VOUT. It is preferable that the control part CNT1 performs a control to provide a dead time in which both the control signals S1 and S2 are at a LOW level.

Further, the control part CNT1 can perform a control using an output OUT2 of a comparator COMP2. For example, the control part CNT1 can perform a constant current control based on an average current flowing through the inductor L1 in each switching period, an overcurrent protection based on the average current flowing in the inductor L1 in each switching period, and the like. In this case, the switching period means a period of switching between the P-channel type MOS field effect transistor Q1 and the N-channel type MOS field effect transistor Q2.

The driver D1 supplies a gate drive signal, which is obtained by amplifying a control signal S1, to a gate of the P-channel type MOS field effect transistor Q1, thereby driving the P-channel type MOS field effect transistor Q1. The driver D2 supplies a gate drive signal, which is obtained by amplifying a control signal S2, to a gate of the N-channel type MOS field effect transistor Q2, thereby driving the N-channel type MOS field effect transistor Q2.

The current detection circuit 300 includes a switch SW1, a resistor R1, and a comparator COMP1. The current detection circuit 300 is supplied with the power supply voltage VCC.

The switch SW1 is provided between each of drains of the P-channel type MOS field effect transistor Q1 and the N-channel type MOS field effect transistor Q2, and the resistor R1 and inverting input terminal of the comparator COMP1. When the control signal S1 is at a HIGH level, the switch SW1 is turned on. When the control signal S1 is at a LOW level, the switch SW1 is turned off. The resistor R1 is a so-called pull-up resistor.

A sense voltage Vsns supplied to the inverting input terminal of the comparator COMP1 is a voltage corresponding to a current flowing through the P-channel type MOS field effect transistor Q1 when the P-channel type MOS field effect transistor Q1 is turned on (a current flowing through the inductor L1 when the P-channel type MOS field effect transistor Q1 is turned on). More specifically, the sense voltage Vsns supplied to the inverting input terminal of the comparator COMP1 is a voltage corresponding to a current flowing through the P-channel type MOS field effect transistor Q1 when the P-channel type MOS field effect transistor Q1 is turned on during a period when the switch SW1 is in the turned-on state, and becomes equal to the power supply voltage VCC during a period when the switch SW1 is in the turned-off state.

Further, the sense voltage Vsns is a voltage generated at a connection node between the P-channel type MOS field effect transistor Q1 and the inductor L1. More specifically, the sense voltage Vsns is a voltage generated at the connection node between the P-channel type MOS field effect transistor Q1 and the inductor L1 during the period when the switch SW1 is in the turned-on state, and becomes equal to the power supply voltage VCC during the period when the switch SW1 is in the turned-off state. In the present embodiment, the sense voltage Vsns is generated by an on-resistance of the P-channel type MOS field effect transistor Q1. Therefore, there is no need to provide a sense resistor for generating the sense voltage Vsns, such that power consumption in the sense resistor can be eliminated. This suppresses a decrease in efficiency of the switching power supply device.

The current detection circuit 300 further includes a P-channel type MOS field effect transistor Q3 and a current source CS0. The P-channel type MOS field effect transistor Q3 and the current source CS0 are an example of a voltage generator configured to generate a threshold voltage Vth. The threshold voltage Vth is supplied to a non-inverting input terminal of the comparator COMP1.

The power supply voltage VCC is applied to a source of the P-channel type MOS field effect transistor Q3, and a gate of the P-channel type MOS field effect transistor Q3 is connected to the ground potential. As a result, the P-channel type MOS field effect transistor Q3 is turned on and becomes a resistance element.

The current source CS0 is provided between a drain of the P-channel type MOS field effect transistor Q3 and the ground potential. The current source CS0 causes a set current (reference current IREF) to flow through the P-channel type MOS field effect transistor Q3. In the present embodiment, a value of the set current (reference current IREF) is fixed to one value, but it may be changeable. For example, when the control part CNT1 performs a current mode control, the value of the set current (reference current IREF) may be changed according to an output signal of an error amplifier (not shown) according to an error between the feedback voltage based on the output voltage VOUT and a reference voltage.

A value (threshold value) of the voltage Vth is a product of the value of the set current (reference current IREF) and a value of an on-resistance of the P-channel type MOS field effect transistor Q3.

In order to suppress power consumption in the voltage generator configured to generate the threshold voltage Vth, it is preferable that the value of the on-resistance of the P-channel type MOS field effect transistor Q3 is large. Therefore, it is preferable that the value of the on-resistance of the P-channel type MOS field effect transistor Q3 is larger than a value of the on-resistance of the P-channel type MOS field effect transistor Q1. For example, the P-channel type MOS field effect transistor Q1 and the P-channel type MOS field effect transistor Q3 may be MOS field effect transistors having different ratios of channel width to channel length. As a result, the on-resistance of the P-channel type MOS field effect transistor Q1 and the on-resistance of the P-channel type MOS field effect transistor Q3 can be easily set to different values.

It is preferable that the P-channel type MOS field effect transistor Q3 is formed so as to maintain pairing property with the P-channel type MOS field effect transistor Q1. When the P-channel type MOS field effect transistors Q1 and Q3 have the pairing property, it is possible to suppress a comparison result by the comparator COMP1 from being influenced by temperature or the like.

The comparator COMP1 compares the sense voltage Vsns and the threshold voltage Vth. An output OUT1 of the comparator COMP1 has a HIGH level when the sense voltage Vsns is smaller than the threshold voltage Vth, and has a LOW level when the sense voltage Vsns is larger than the threshold voltage Vth.

The current detection circuit 300 further includes a P-channel type MOS field effect transistor Q4, current sources CS1 and CS2, capacitors C1 and C2, and N-channel type MOS field effect transistors Q5 and Q6. The P-channel type MOS field effect transistor Q4, the current sources CS1 and CS2, the capacitors C1 and C2, and the N-channel type MOS field effect transistors Q5 and Q6 are an example of a determiner. The determiner in the present embodiment determines, based on an output of the comparator COMP1, whether or not a timing at which a magnitude relationship between the sense voltage Vsns and the threshold voltage Vth is reversed after the P-channel MOS field effect transistor Q1 is turned on is before a predetermined time elapses after the P-channel type MOS field effect transistor Q1 is turned on.

The capacitor C1 is charged with a first constant current I1 until a magnitude relationship between the sense voltage Vsns and the threshold voltage Vth is reversed after the P-channel type MOS field effect transistor Q1 is turned on, by the P-channel type MOS field effect transistor Q4 and the current source CS1 configured to output the first constant current I1. A value of a charging voltage V1 of the capacitor C1 at the timing when the magnitude relationship between the sense voltage Vsns and the threshold voltage Vth is reversed is held until the P-channel type MOS field effect transistor Q1 is turned off.

The capacitor C2 is charged with a second constant current I2 after the magnitude relationship between the sense voltage Vsns and the threshold voltage Vth is reversed, by the current source CS2 configured to output the second constant current I2.

The N-channel type MOS field effect transistor Q5 discharges the capacitor C1 while the P-channel type MOS field effect transistor Q1 is being turned off.

An inverter INV1 and the N-channel type MOS field effect transistor Q6 discharge the capacitor C2 during a period from when the P-channel type MOS field effect transistor Q1 is turned on until the magnitude relationship between the sense voltage Vsns and the threshold voltage Vth is reversed and during a period when the P-channel type MOS field effect transistor Q1 is turned off.

The current detection circuit 300 further includes a comparator COMP2. The comparator COMP2 compares the charging voltage V1 of the capacitor C1 and a charging voltage V2 of the capacitor C2. An output OUT2 of the comparator COMP2 has a LOW level when the charging voltage V1 of the capacitor C1 is larger than the charging voltage V2 of the capacitor C2, and has a HIGH level when the charging voltage V1 of the capacitor C1 is smaller than the charging voltage V2 of the capacitor C2.

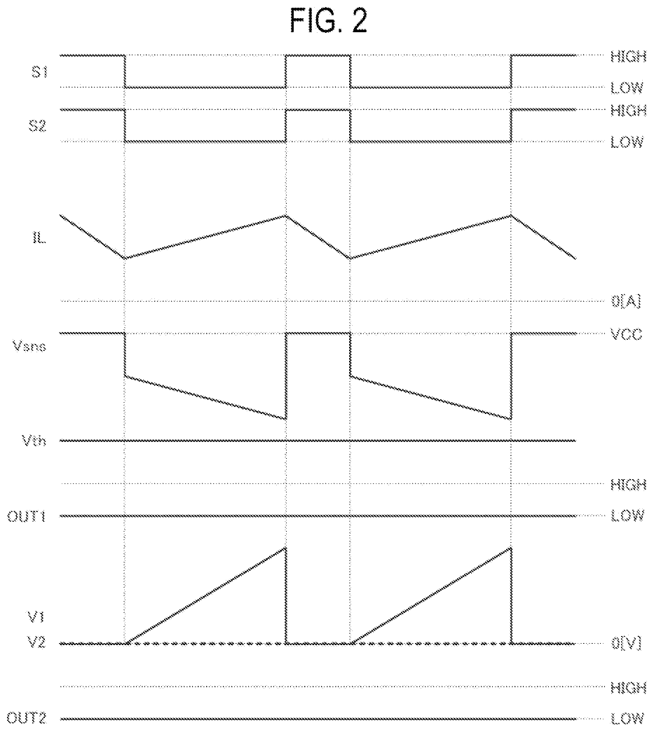

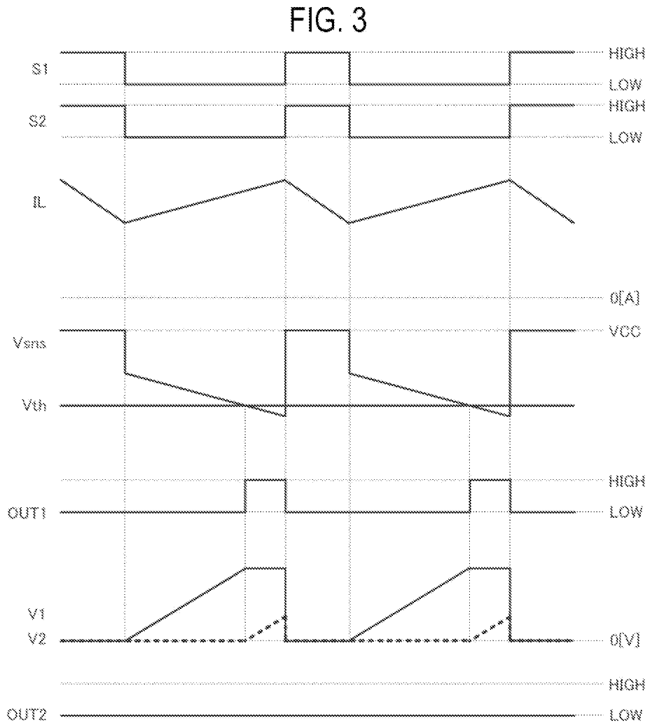

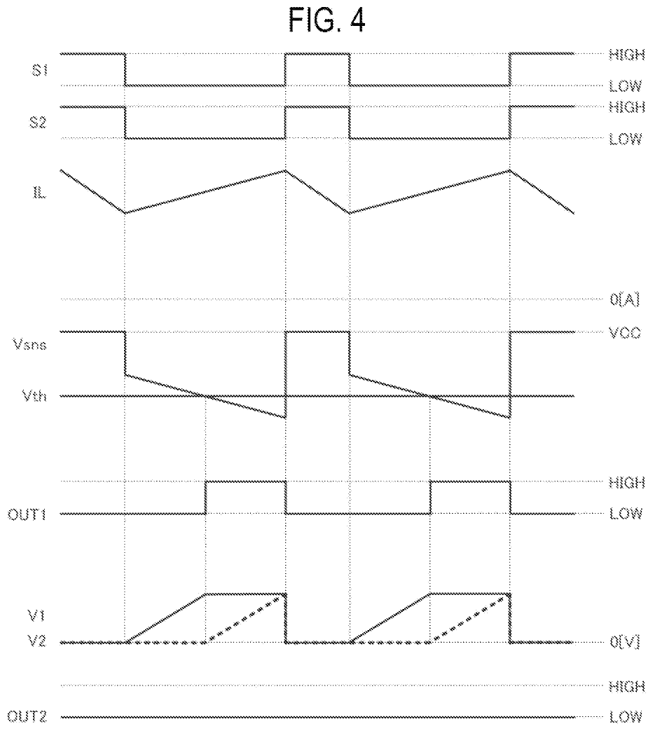

FIGS. 2 to 5 are diagrams showing operation examples of the current detection circuit 300. In FIGS. 2 to 5, the control signal S1, the control signal S2, a current IL flowing through the inductor L1, the sense voltage Vsns, the threshold voltage Vth, the output OUT1 of the comparator COMP1, the charging voltage V1 of the capacitor C1, the charging voltage V2 of the capacitor C2, and the output OUT2 of the comparator COMP2 are depicted from top to bottom. The charging voltage V2 of the capacitor C2 is depicted by a broken line.

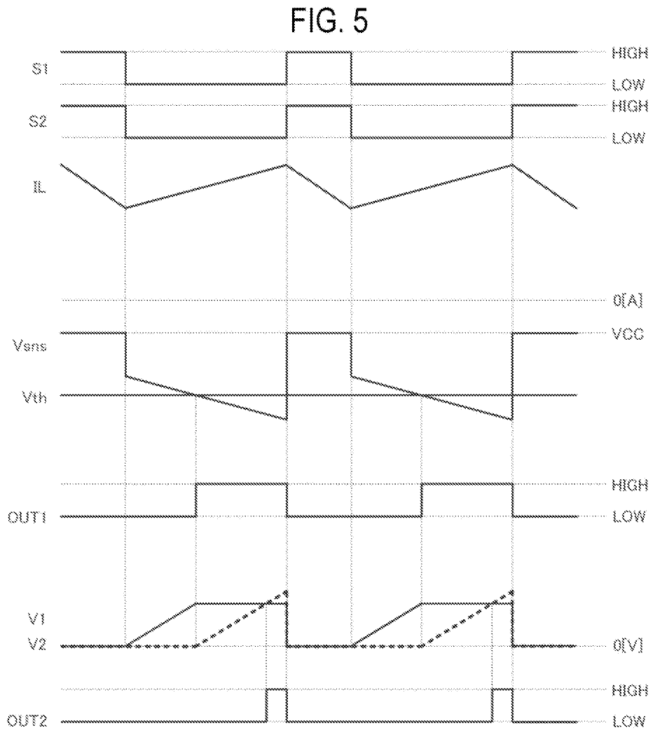

As the operation moves from FIG. 2 to FIG. 5, an average value of the current IL flowing through the inductor L1 increases. That is, FIG. 2 is a state in which the average value of the current IL flowing through the inductor L1 is the smallest among four states shown in FIGS. 2 to 5. Conversely, FIG. 5 is a state in which the average value of the current IL flowing through the inductor L1 is the largest among the four states shown in FIGS. 2 to 5.

For example, in a case where the first constant current I1 and the second constant current I2 have the same value, and a capacitance of the capacitor C1 and a capacitance of the capacitor C2 are the same, it can be confirmed by the output OUT2 of the comparator COMP2 whether or not the current IL flowing through the inductor L1 exceeds a predetermined value (a value corresponding to the threshold voltage Vth) at a timing earlier than a half of the period during which the P-channel type MOS field effect transistor Q1 is turned on.

As shown in FIGS. 2 to 4, when no pulse appears at the output OUT2 of the comparator COMP2, the current IL flowing through the inductor L1 does not exceed the set value (the value corresponding to the threshold voltage Vth) at a timing earlier than a half of the period during which the P-channel type MOS field effect transistor Q1 is turned on.

As shown in FIG. 5, when a pulse appears at the output OUT2 of the comparator COMP2, the current IL flowing through the inductor L1 exceeds the set value (the value corresponding to the threshold voltage Vth) at the timing earlier than a half of the period during which the P-channel type MOS field effect transistor Q1 is turned on.

There is a correlation between an instantaneous value of the current IL, which flows through the inductor L1 when a predetermined time (for example, a half the period during which the P-channel type MOS field effect transistor Q1 is turned on) has elapsed after the P-channel type MOS field effect transistor Q1 is turned on, and the average value of the current IL flowing through the inductor L1 during the switching period. Therefore, the current detection circuit 300 can detect whether or not the average value of the current IL flowing through the inductor L1 for each switching period is larger than the set value.

For example, as the control part CNT1 performs a control to reduce the current IL flowing through the inductor L1 when a pulse appears at the output OUT2 of the comparator COMP2 and, conversely, performs a control to increase the current IL flowing through the inductor L1 when no pulse appears at the output OUT2 of the comparator COMP2, the average value of the current IL flowing through the inductor L1 for each switching period can be maintained near the set value.

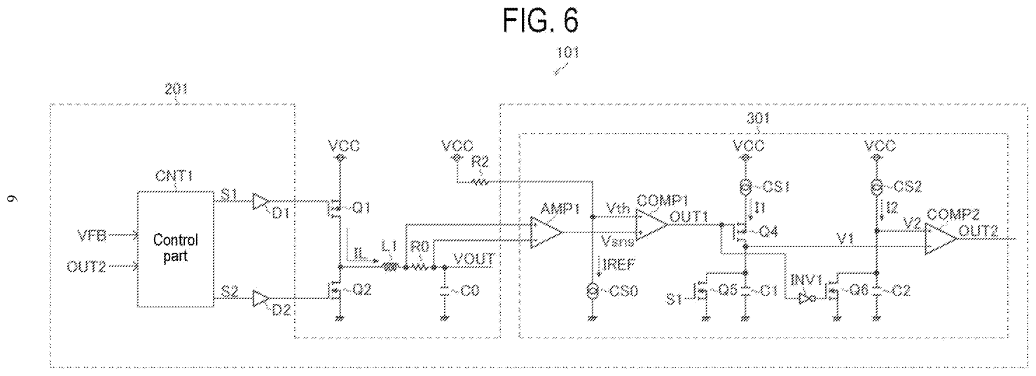

FIG. 6 is a diagram showing a configuration of a switching power supply device according to a modification. The switching power supply device 101 is different from the above-described switching power supply device 100 in that the former includes a sense resistor R0, a resistor R2, and a switching power supply controller 201 instead of the switching power supply controller 200.

The sense resistor R0 is connected in series with the inductor L1 and is provided in the previous stage of the output capacitor C0. The resistor R2 is a resistive element that has a larger resistance value than the sense resistor R0 and has the same temperature characteristics as the sense resistor R0.

The switching power supply controller 201 is different from the above-described switching power supply controller 200 in that the former includes a current detection circuit 301 instead of the current detection circuit 300.

The current detection circuit 301 is different from the current detection circuit 300 in that the former includes an amplifier AMP1 instead of the switch SW and the resistor R1 and does not include the P-channel type MOS field effect transistor Q3, and the non-inverting input terminal and the inverting input terminal of the comparator COMP1 are swapped. The amplifier AMP1 generates the sense voltage Vsns according to the potential difference between both ends of the sense resistor R0 and supplies the sense voltage Vsns to the non-inverting input terminal of the comparator COMP1. The above-described resistor R2 is a resistive element that replaces the P-channel type MOS field effect transistor Q3.

### Application Examples

Application examples of the current detection circuit are not limited to switching power supply devices. The current detection circuit configured as described above may be installed in, for example, a light emitting element driver, a motor driver, or the like.

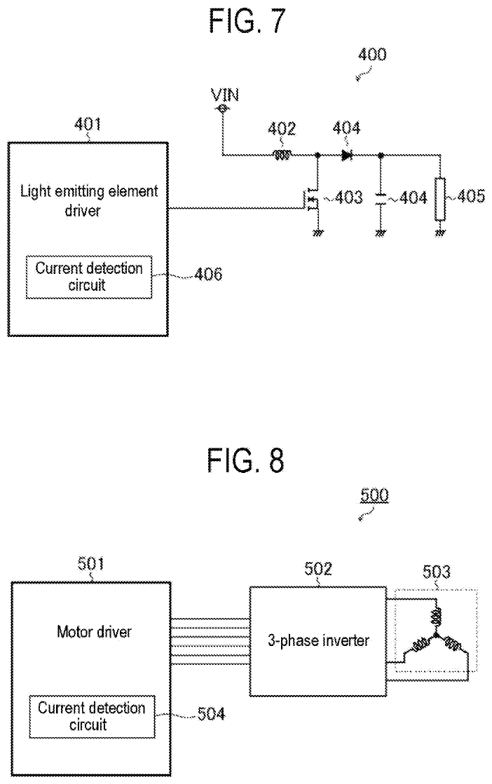

FIG. 7 is a diagram showing a schematic configuration example of a light emitting device. The light emitting device 400 includes a light emitting element driver 401, an inductor 402, an N-channel type MOS field effect transistor 403, an output capacitor 404, and a light emitting element 405. The light emitting element driver 401 drives the light emitting element 405 by controlling the N-channel type MOS field effect transistor 403. The light emitting element driver 401 includes a current detection circuit 406.

FIG. 8 is a diagram showing a schematic configuration example of a motor device. A motor device 500 includes a motor driver 501, a 3-phase inverter 502, and a 3-phase motor 503. The motor driver 501 drives the 3-phase motor 503 by controlling the 3-phase inverter 502. The motor driver 501 includes a current detection circuit 504.

### <Others>

In addition to the above-described embodiments, a configuration of the present disclosure can be modified in various ways without departing from the spirit of the present disclosure. The above-described embodiments should be considered as being illustrative in all respects and not restrictive. Further, the technical scope of the present disclosure is defined by the claims, not by the descriptions in the above-described embodiments, and it should be understood that the technical scope of the present disclosure includes all changes that fall within the meaning and range equivalent to the claims.

In the above-described embodiments, the sense voltage is a voltage that corresponds to a current flowing through a high-side switching element, but it may also be a voltage that corresponds to a current flowing through a low-side switching element. Further, the low-side switching element may be, for example, a diode.

### <Supplementary Notes>

Supplementary notes will be provided for the present disclosure in which specific configuration examples are shown in the above-described embodiments.

A current detection circuit (300, 301, 406, 504) of the present disclosure has a configuration (first configuration) that it includes: a first comparator (COMP1) configured to compare a sense voltage, which corresponds to a current flowing through a switching element (Q1) when the switching element is turned on, and a threshold voltage; and a determiner (C1, C2, CS1, CS2, Q4 to Q6, INV1, COMP2) configured to determine, based on an output of the first comparator, whether or not a timing at which a magnitude relationship between the sense voltage and the threshold voltage is reversed after the switching element is turned on is before a predetermined time elapses after the switching element is turned on.

According to the current detection circuit of the first configuration, an average current for each switching period can be detected. More specifically, according to the current detection circuit of the first configuration, it is possible to detect whether or not the average current for each switching period is larger than a set value. Therefore, by using the current detection circuit of the first configuration, it is possible to realize, for example, a constant current control based on the average current for each switching period, an overcurrent protection based on the average current for each switching period, and the like.

The current detection circuit of the first configuration may have a configuration (second configuration) that the sense voltage may be a voltage generated at a connection node between the switching element and an inductor (L1).

The current detection circuit of the first or second configuration may have a configuration (third configuration) that the determiner includes: a first charger (CS1, Q4, C1) configured to be charged with a first constant current until the magnitude relationship between the sense voltage and the threshold voltage is reversed after the switching element is turned on; a second charger (CS2, C2) configured to be charged with a second constant current after the magnitude relationship between the sense voltage and the threshold voltage is reversed; and a second comparator (COMP2) configured to compare a charging voltage of the first charger and a charging voltage of the second charger.

The current detection circuit of the third configuration may have a configuration (fourth configuration) that the determiner includes: a first discharger (Q5) configured to discharge the first charger during a period when the switching element is turned off; and a second discharger (Q6, INV1) configured to discharge the second charger during a period from when the switching element is turned on until the magnitude relationship between the sense voltage and the threshold voltage is reversed and during a period when the switching element is turned off.

The current detection circuit of any one of the first to fourth configurations may have a configuration (fifth configuration) that it further includes: a voltage generator configured to generate the threshold voltage, wherein the voltage generator includes: a resistance element (Q3) whose resistance value is larger than an on-resistance of the switching element; and a current source (CS0) configured to cause a set current to flow through the resistance element. The current detection circuit of the fifth configuration may have a configuration (sixth configuration) that the switching element and the resistance element are MOS field effect transistors having different ratios of channel width to channel length.

A switching power supply controller (200, 201) of the present disclosure has a configuration (seventh configuration) that it includes the current detection circuit of any one of the first to sixth configurations.

A light emitting element driver (401) of the present disclosure has a configuration (eighth configuration) that it includes the current detection circuit of any one of the first to sixth configurations.

A motor driver (501) of the present disclosure has a configuration (ninth configuration) that it includes the current detection circuit of any one of the first to sixth configurations.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A current detection circuit comprising:
a first comparator configured to compare a sense voltage, which corresponds to a current flowing through a switching element when the switching element is turned on, and a threshold voltage; and
a determiner configured to determine, based on an output of the first comparator, whether or not a timing at which a magnitude relationship between the sense voltage and the threshold voltage is reversed after the switching element is turned on is before a predetermined time elapses after the switching element is turned on.

2. The current detection circuit of claim 1, wherein the sense voltage is a voltage generated at a connection node between the switching element and an inductor.

3. The current detection circuit of claim 1, wherein the determiner includes:
a first charger configured to be charged with a first constant current until the magnitude relationship between the sense voltage and the threshold voltage is reversed after the switching element is turned on;
a second charger configured to be charged with a second constant current after the magnitude relationship between the sense voltage and the threshold voltage is reversed; and
a second comparator configured to compare a charging voltage of the first charger and a charging voltage of the second charger.

4. The current detection circuit of claim 3, wherein the determiner includes:
a first discharger configured to discharge the first charger during a period when the switching element is turned off; and
a second discharger configured to discharge the second charger during a period from when the switching element is turned on until the magnitude relationship between the sense voltage and the threshold voltage is reversed and during the period when the switching element is turned off.

5. The current detection circuit of claim 1, further comprising a voltage generator configured to generate the threshold voltage,
wherein the voltage generator includes:
a resistance element whose resistance value is larger than an on-resistance of the switching element; and
a current source configured to cause a set current to flow through the resistance element.

6. The current detection circuit of claim 5, wherein the switching element and the resistance element are MOS field effect transistors having different ratios of channel width to channel length.

7. A switching power supply controller comprising the current detection circuit of claim 1.

8. A light emitting element driver comprising the current detection circuit of claim 1.

9. A motor driver comprising the current detection circuit of claim 1.
